(19) United States
(12) Patent Application Publication
(10) Pub. No.: US 2006/0043316 A1
(43) Pub. Date: Mar. 2, 2006

(54) Ion implanter having enhanced low energy ion beam transport

(75) Inventors: Reuel B. Liebert, Peabody, MA (US); Harold Persing, Rockport, MA (US); James Buff, Brookline, NH (US)

Correspondence Address: Mark A. Superko, Esq.;Varian Semiconductor Equipment, Associates, Inc., 35 Dory Road, Gloucester, MA, 01930, US

(73) Assignee: Varian Semiconductor Equipment Associates, Inc., Gloucester, MA (US)

(21) Appl. No.: 10/458,037

(22) Filed: Jun. 10, 2003

(51) Int. Cl. H01J 37/08

(52) U.S. Cl. 250/492.21

(57) ABSTRACT

An ion implanter includes an ion source for generating an ion beam, a target site for supporting a target for ion implantation and a beamline defining a beam path between the ion source and the target site. In one aspect, a magnetic steerer is disposed between the ion source and the target site for at least partially correcting unwanted deviation of the ion beam from the beam path. The magnetic steerer may position the ion beam relative to an entrance aperture of an ion optical element. In another aspect, the beamline includes a deceleration stage for decelerating the ion beam from a first transport energy to a second transport energy. The deceleration stage includes two or more electrodes, wherein at least one of the electrodes is a grid electrode positioned in the beam path.

### FIELD OF THE INVENTION

This invention relates to systems and methods for ion implantation and, more particularly, to methods and apparatus for delivery of low energy, monoenergetic ion beams to an ion implantation target, such as a semiconductor wafer.

### BACKGROUND OF THE INVENTION

Ion implantation has become a standard technique for introducing conductivity-altering impurities into semiconductor wafers. A desired impurity material is ionized in an ion source, the ions are accelerated to form an ion beam of prescribed energy and the ion beam is directed at the surface of the wafer. The energetic ions in the beam penetrate into the bulk of the semiconductor material and are embedded into the crystalline lattice of the semiconductor material to form a region of desired conductivity.

Ion implantation systems usually include an ion source for converting a gas or solid material into a well-defined ion beam. The ion beam is mass analyzed to eliminate undesired ion species, is accelerated to a desired energy and is directed onto a target plane. The beam may be distributed over the target area by beam scanning, by target movement or by a combination of beam scanning and target movement.

U.S. Pat. No. 5,350,926 issued Sep. 27, 1994 to White et al. discloses a high current, broad beam ion implanter which employs a high current density ion source, an analyzing magnet to direct a desired species through a resolving aperture and an angle corrector magnet to deflect the resultant beam, while rendering it parallel and uniform along its width dimension. A ribbon-shaped beam is delivered to a target, and the target is moved perpendicular to the long dimension of the ribbon beam to distribute the ion beam over the target.

A well-known trend in the semiconductor industry is toward smaller, higher speed devices. Both the lateral dimensions and the depths of features in semiconductor devices are decreasing. State of the art semiconductor devices require junction depths less than 300 Angstroms and may eventually require junction depths on the order of 100 Angstroms or less.

The implanted depth of the dopant material is determined, at least in part, by the energy of the ions implanted into the semiconductor wafer. Shallow junctions are obtained with low implant energies. However, ion implanters are typically designed for efficient operation at relatively high implant energies, for example in the range of 20 keV to 400 keV, and may not function efficiently at the energies required for shallow junction implantation. At low implant energies, such as energies of 2 keV and lower, the current delivered to the wafer is much lower than desired and in some cases may be near zero. As a result, extremely long implant times are required to achieve a specified dose, and throughput is adversely affected. Such reduction in throughput increases fabrication cost and is unacceptable to semiconductor device manufacturers.

In one prior art approach to low energy ion implantation, the ion implanter is operated in a drift mode with the accelerator turned off. Ions are extracted from the ion source at low voltage and simply drift from the ion source to the target semiconductor wafer. However, a small ion current is delivered to the wafer because the ion source operates inefficiently at low extraction voltages. In addition, the beam expands as it is transported through the ion implanter, and ions may strike components of the ion implanter along the beamline rather than the target semiconductor wafer.

Ion implanters which use deceleration modes for low energy ion beams either use a single bending magnet for mass analysis or two magnets. In the two magnet case, the first magnet is used for mass analysis and the second magnet is used to parallelize the beam. Ion beam transport is efficient at high energies and is less efficient at low energies due to effects of space charge neutralization loss and beam blowup. These effects are particularly severe in regions of electrical fields, such as deceleration gaps needed to decelerate the beam from initial energies of beam generation and transport to the desired final lower energy.

A deceleration following a single magnet is accompanied by some level of beam contamination which results from beam which neutralizes either in residual gas or by small angle scattering from surfaces before the beam is decelerated to its final energy. This neutralized beam has a higher energy than the desired final beam energy and may have a direct line of sight path to the wafer being implanted. The result is impaired electrical performance of the devices being manufactured using the implanter.

Using a second magnet makes it possible to achieve much of the deceleration before the final bend and thereby eliminate the line of sight path for ions neutralized in the deceleration field or upstream of the deceleration field. The ion beam can either drift through the second magnet to the wafer or a second deceleration can be used following the second magnet. In the first case, energy contamination is almost completely eliminated but the beam must be transported at its lowest energy a long distance to the wafer. In the second case, the final deceleration can be achieved with a much lower field and with a very low production of energy contamination. The main obstacle to good performance is the efficiency of transport of the ion beam through the second magnet and to the wafer following its first deceleration. Typically, an ion beam which is optimized for such a system may have severe aberrations due to transport in the first magnet, and the aberrant beams are difficult to match into the entrance aperture of the second magnet when the energy is low and the deceleration stage between the magnets is used.

The mismatch is exacerbated by small angle errors in centration (in the plane perpendicular to the analyzing magnet median plane) which result from magnetic fields in the ion source. Correction of these errors using extraction manipulators to offset the extraction fields of the ion source only approximately corrects the angle. This defect is minor at high energies when the beam is small in the direction of the error. However, at low energies and also after deceleration and transport over a long distance, the angle error can prevent complete transmission through the second magnet. In addition, beam blowup from space charge expansion in the deceleration region can cause overfill of the pole gap of the second magnet. Beam efficiency suffers as a result.

Accordingly, there is a need for improved methods and apparatus for enhancing low energy ion beam transport.

### SUMMARY OF THE INVENTION

According to a first aspect of the invention, an ion implanter is provided. The ion implanter comprises an ion source for generating an ion beam, a target site for supporting a target for ion implantation, a beamline defining a beam path between the ion source and the target site, and a magnetic steerer disposed between the ion source and the target site for at least partially correcting an unwanted deviation of the ion beam from the beam path.

The magnetic steerer may comprise a closed-loop magnetic frame having an opening for passing the ion beam and one or more electrical coils on the frame for producing a magnetic field in the opening. The magnetic frame may include top, bottom, left-side and right-side segments. The magnetic steerer may include electrical coils on the top and bottom segments of the magnetic frame, on the left-side and right-side segments of the magnetic frame, or both. The coils are energized so that the fields in the material of the magnetic frame induced by opposite coils oppose each other and so that the magnetic field in the center of the frame is fed by each coil. By adjusting the ratio of horizontal to vertical coil currents, the steering in x and y directions can be independently adjusted.

The beamline may comprise an analyzing magnet positioned upstream of the magnetic steerer for separating different ion species in an analysis plane and a resolving mask having a resolving aperture positioned downstream of the magnetic steerer. The magnetic steerer can alter the angles of the beam so that a beam which is off the central beamline axis either can be brought back on the axis at a desired point or adjusted to be parallel to that axis. In combination with an analyzing magnet, both objectives can be achieved in the resolving plane. When a second steering element is used either before or after such a magnet, the beam can be brought into the median resolving plane and parallel to the desired axis. The beamline may further comprise a deceleration stage positioned downstream of the resolving mask and an angle corrector magnet positioned downstream of the deceleration stage.

According to another aspect of the invention, an ion implanter is provided. The ion implanter comprises an ion source for generating an ion beam, an analyzer for separating unwanted components from the ion beam, wherein the ion beam is transported through the analyzer at a first transport energy, a deceleration stage positioned downstream of the analyzer for decelerating the ion beam from the first transport energy to a second transport energy, the deceleration stage comprising an upstream electrode and a deceleration electrode, wherein at least one of the electrodes comprises a grid electrode positioned in the beam path, and a target site for supporting a target for ion implantation.

The grid electrode may comprise plural spaced conductors defining openings for passing the ion beam. In some embodiments, the grid electrode comprises a first set of spaced-apart parallel conductors and a second set of spaced-apart parallel conductors, wherein the conductors in the first set are orthogonal to the conductors in the second set. In other embodiments, the grid electrode comprises parallel spaced-apart conductors. In further embodiments, the grid electrode comprises a conductor having multiple openings for passing the ion beam.

In one embodiment, the deceleration electrode comprises a grid electrode. In another embodiment, the deceleration stage further comprises a suppression electrode between the upstream and deceleration electrodes, and the suppression electrode comprises a grid electrode. In a further embodiment, each of the electrodes of the deceleration stage comprises a grid electrode.

According to a further aspect of the invention, an ion implanter is provided. The ion implanter comprises an ion source for generating an ion beam, a target site for supporting a target for ion implantation, and a grid electrode disposed between the ion source and the target site for altering at least one parameter of the ion beam, the grid electrode having multiple openings for passing the ion beam.

According to a further aspect of the invention, a method for implanting ions in a target is provided. The method comprises generating an ion beam, supporting a target at a target site for ion implantation, transporting the ion beam along a beam path between the ion source and the target site, and at least partially correcting an unwanted deviation of the ion beam from the beam path using a magnetic steerer disposed between the ion source and the target site.

According to a further aspect of the invention, a method for implanting ions in a target is provided. The method comprises generating an ion beam, separating unwanted components from the ion beam in an analyzer, transporting the ion beam through the analyzer at a first transport energy, decelerating the ion beam from the first transport energy to a second transport energy in a deceleration stage comprising two or more electrodes, wherein at least one of the electrodes comprises a grid electrode disposed in the beam path, and delivering the decelerated ion beam to a target site.

### BRIEF DESCRIPTION OF THE DRAWINGS

For a better understanding of the present invention, reference is made to the accompanying drawings, which are incorporated herein by reference and in which:

FIG. 1 is a simplified schematic diagram of an embodiment of an ion implanter;

FIG. 2 is a graph of beam energy as a function of distance along the beamline in the ion implanter of FIG. 1;

FIG. 3 is a top view of a section of the ion implanter beamline in accordance with a first embodiment of the invention;

FIG. 4 is a top view of a section of the ion implanter beamline in accordance with a second embodiment of the invention;

FIG. 5 is a top view of a section of the ion implanter beamline in accordance with a third embodiment of the invention;

FIG. 6 is a schematic diagram of an embodiment of a magnetic steerer, as viewed in the direction of ion beam transport, and associated system elements;

FIG. 7 is a schematic view of a first embodiment of a deceleration stage utilizing grid electrodes;

FIG. 8 is a schematic view of a second embodiment of a deceleration stage utilizing a grid electrode;

FIG. 9 is a schematic diagram of a first embodiment of a grid electrode, as viewed in the direction of ion beam transport; and

FIG. 10 is a schematic diagram of a second embodiment of a grid electrode, as viewed in the direction of ion beam transport.

### DETAILED DESCRIPTION

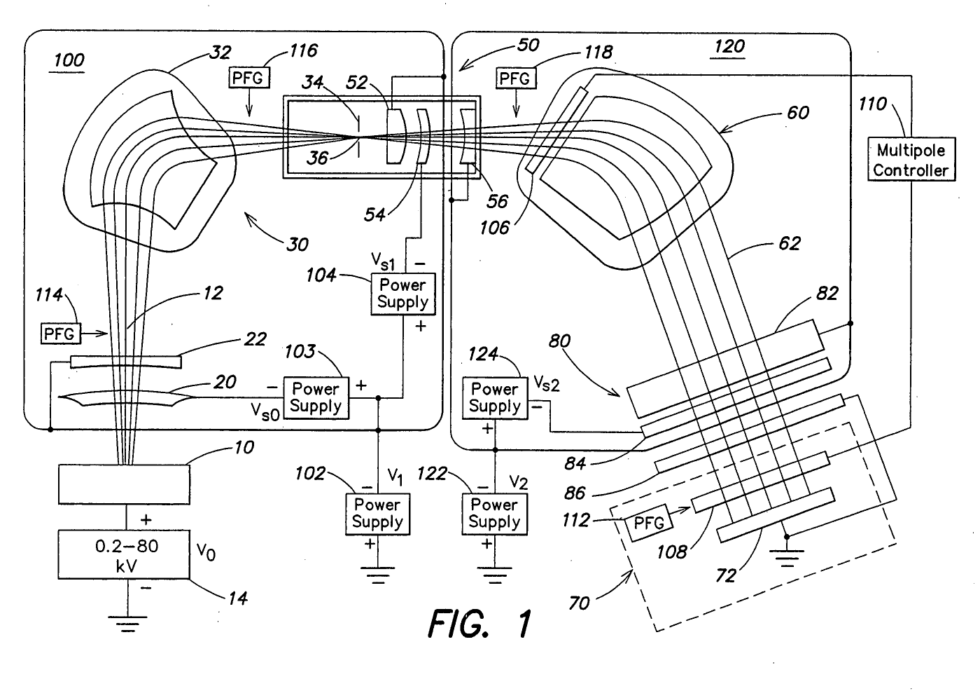

A block diagram of an example of an ion implanter is shown in FIG. 1. An ion source 10 generates ions and supplies an ion beam 12. As known in the art, ion source 10 may include an ion chamber and a gas box containing a gas to be ionized. The gas is supplied to the ion chamber where it is ionized. The ions thus formed are extracted from the ion chamber to form ion beam 12. Ion beam 12 has an elongated cross section and is ribbon-shaped, with a long dimension of the beam cross section preferably having a horizontal orientation. A first power supply 14 is connected to an extraction electrode of ion source 10 and provides a positive first voltage V₀. First voltage V₀ may be adjustable, for example, from about 0.2 to 80 kV. Thus, ions from ion source 10 are accelerated to energies of about 0.2 to 80 keV by the first voltage V₀. The construction and operation of ion sources are well known to those skilled in the art.

Ion beam 12 passes through a suppression electrode 20 and a ground electrode 22 to a mass analyzer 30. The ion source 10 may use a magnetic field whose fringe area can extend to the region between electrode 20 and analyzer 30. This field can cause an undesired ion beam deflection which could displace the ion beam from its desired bending plane in the magnet 30 and/or displace the ion beam from centration with respect to the desired beam path. In some cases, electrodes 20 and 22 are made movable or are intentionally displaced from their aligned position to partially compensate the undesired deflections. A single compensation is not sufficient to correct both angle and position of a beam which has undergone a deflection. The mass analyzer 30 includes an analyzing magnet 32 and a resolving mask 34 having a resolving aperture 36. Analyzing magnet 32 deflects ions in ion beam 12 such that ions of a desired ion species pass through resolving aperture 36 and undesired ion species do not pass through resolving aperture 36 but are blocked by the resolving mask 34. In a preferred embodiment, analyzing magnet 32 deflects ions of the desired species by 90°.

Ions of the desired ion species pass through resolving aperture 36 to a first deceleration stage 50 positioned downstream of mass analyzer 30. Deceleration stage 50 may include an upstream electrode 52, a suppression electrode 54 and a downstream electrode 56. Ions in the ion beam are decelerated by deceleration stage 50 as described below and then pass through an angle corrector magnet 60. Angle corrector magnet 60 deflects ions of the desired ion species and converts the ion beam from a diverging ion beam to a ribbon ion beam 62 having substantially parallel ion trajectories. The ribbon ion beam 62 has a cross section with a relatively large width and a relatively small height and thus resembles a ribbon. In a preferred embodiment, angle corrector magnet 60 deflects ions of the desired ion species by 70°.

An end station 70 supports one or more workpieces, such as wafer 72, in the path of ribbon ion beam 62 such that ions of the desired species are implanted into the semiconductor wafers. The end station 70 may include a target site in the form of a cooled electrostatic platen and a scanner for moving wafer 72 perpendicular to the long dimension of the ribbon ion beam 62 cross section, so as to distribute ions over the surface of wafer 72. The ion implanter may include a second deceleration stage 80 positioned downstream of angle corrector magnet 60. Deceleration stage 80 may include an upstream electrode 82, a suppression electrode 84 and a downstream electrode 86.

The ion implanter may include additional components known to those skilled in the art. For example, end station 70 typically includes automated wafer handling equipment for introducing wafers into the ion implanter and for removing wafers after implantation. End station 70 may also include a dose measuring system, an electron flood gun and other components. It will be understood that the entire path traversed by the ion beam is evacuated during ion implantation. The implanter components between ion source 10 and the target site constitute a beamline which defines a beam path between the ion source and the target site.

A beamline module 100, comprising mass analyzer 30, ground electrode 22, and electrode 52 of deceleration stage 50, is coupled to a second power supply 102. Suppression electrode 20 and ground electrode 22 may move as a unit. A second voltage V₁, generated by power supply 102, is coupled to the components of beamline module 100 and accelerates ion beam 12 to an energy that is sufficient for transport without excessive beam expansion. Typically, power supply 102 is adjusted to provide a negative transport voltage up to −30 kV relative to ground potential. A power supply 103, referenced to power supply 102, is used to bias suppression electrode 20 more negatively than beamline module 100 potential V₁ (electrode 22 potential) by a voltage V_{S0} sufficiently negative to suppress the flow of electrons in the ion beam from one energy region to another. A power supply 104, referenced to power supply 102, is used to bias suppression electrode 54 more negatively than the beamline module 100 potential V₁ (electrode 52 potential) by a voltage V_{S1} sufficiently negative to suppress the flow of electrons in the ion beam from one energy region to another and to provide the beam optical focusing needed to maximize transport of the beam through the downstream elements of the beamline.

A second beamline module 120 comprises downstream electrode 56 of deceleration stage 50, angle corrector magnet 60 and electrode 82 of deceleration stage 80, which are coupled to a third power supply 122. Power supply 122 generates a negative voltage V₂, typically up to −5 kV. A power supply 124, referenced to power supply 122, is used to bias suppression electrode 84 more negatively than the beamline module 120 potential (electrode 82 potential) by a voltage VS₂ sufficiently negative to suppress the flow of electrons from one energy region to another and to optimize the beam transmission to the target wafer 72. The supply voltage V₂ applied to the components of beamline module 120 decelerates the ion beam 12 from the energy established by beamline module 100 to a second transport energy established by beamline module 120. The downstream electrode 86 of deceleration stage 80 is grounded, so that the ion beam is further decelerated to the final energy E_{F}=qᵢ (V₀) established by power supply 14 before the ions are implanted into wafer 72.

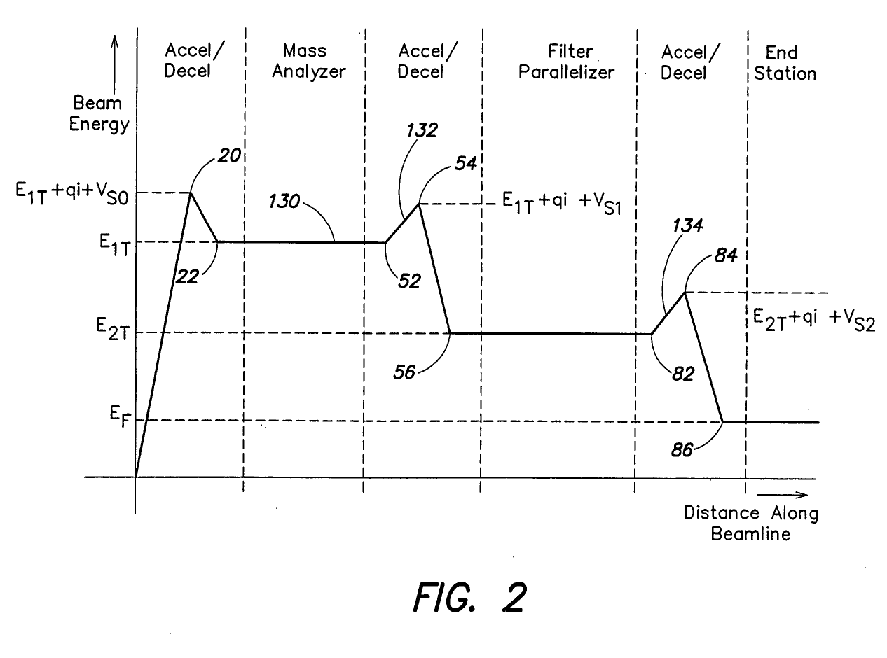

FIG. 2 is a graph of beam energy as a function of distance along the beamline. Curve 130 represents beam energy in the ion implanter, and reference numbers 20, 22, 52, 54, 56, 82, 84, and 86 indicate the locations of the corresponding electrodes along the beamline. Ion beam 12 is extracted from ion source 10 by the combined potentials V₀+V_{1 +V}_{S0} supplied by power supplies 14, 102 and 103, respectively. The ion beam 12 is then decelerated to the first transport energy E_{1T}=qᵢ (V₀+V₁) prior to entering mass analyzer 30. As the beam 12 exits the beamline module 100, it is accelerated to energy E=qᵢ (V₀+V₁+V_{S1}) by the bias on suppression electrode 54, as indicated by energy increase 132. The ion beam is then decelerated at electrode 56 to a second transport energy E_{2T}=qᵢ (V₀+V₂), where V₂ is determined by power supply 122. The beam is transported through angle corrector magnet 60 at the second transport energy E_{2T}. As the beam exits the beamline module 120, it is accelerated to energy E=qᵢ (V₀+V₂+V_{S2}) by the bias on suppression electrode 84, as indicated by energy increase 134. The ion beam 12 is then decelerated at electrode 86 to final energy E_{F}=qᵢ (V₀), and the beam is delivered to wafer 72 in end station 70 at final energy E_{F}. The final implantation energy delivered to wafer 72 is the ion charge qᵢ times the ion source potential V₀ established by extraction power supply 14.

In summary, first power supply 14 provides first voltage V₀, second power supply 102 provides second voltage V₁, and third power supply 122 provides third voltage V₂. The ion beam 12 is transported through analyzer 30 at the first transport energy E_{1T}=qᵢ (V₀+V₁), is transported through angle corrector magnet 60 at the second transport energy E_{2T}=qᵢ (V₀+V₂) and is delivered to wafer 72 at final energy E_{F}=qᵢ (V₀).

The ion implanter may further include a beam sensing and control assembly for adjusting the ribbon ion beam 62 to be substantially uniform across its width (in the plane shown in FIG. 1). The beam sensing and control assembly includes a multipole element 106, a beam profiler 108 and a multipole controller 110. The multipole element 106 adjusts the uniformity of ribbon ion beam 62 in response to control signals from multipole controller 110. The beam profiler 108, positioned to intercept ribbon ion beam 62, senses the uniformity of ribbon ion beam 62 and provides a sense signal to multipole controller 110.

As noted above, space charge expansion of the ion beam is particularly severe in the case of low energy ion beams. One way to limit space charge expansion of the ion beam is to provide electrons which form a cloud that largely neutralizes the region of passage of the ion beam and thereby reduces the electric field tending to produce space charge expansion. One or more electron generators in the form of electron sources or plasma flood guns (PFG) may be utilized in the ion implanter to reduce the effect of space charge induced beam expansion. As shown in FIG. 1, a plasma flood gun 112 may be located in front of wafer 72 to limit space charge expansion and to limit charge buildup on the surface of wafer 72. A plasma flood gun 114 may be located at the entrance to analyzing magnet 32, and/or a plasma flood gun 116 may be located at the exit of analyzing magnet 32. A plasma flood gun 118 may be located at the entrance of angle corrector magnet 60.

The operating mode of the ion implanter shown in FIG. 2 and described above is known as the “double deceleration” mode. In another operating mode, known as the “enhanced drift” mode, power supplies 122 and 124 are turned off and/or disconnected, and beamline module 120 and suppression electrode 84 are connected to ground. Because the ion beam 12 is transported through beamline module 100 at relatively high energy, beam expansion is limited. In another operating mode, which is a special case of the configuration shown in FIG. 1 and described above, beamline module 100 and beamline module 120 are electrically connected together to form a single stage deceleration system. In this operating mode, known as “process chamber decel”, beamline modules 100 and 120 are biased by one of power supplies 102 and 122, and deceleration of the ion beam occurs at deceleration stage 80. In yet another operating mode, known as the “drift” mode, beamline modules 100 and 120 are both grounded. Thus, ion beam 12 is transported through the beamline components at final energy E_{F}=qᵢ(V₀) established by power supply 14 and is delivered to wafer 72 at final energy E_{F}.

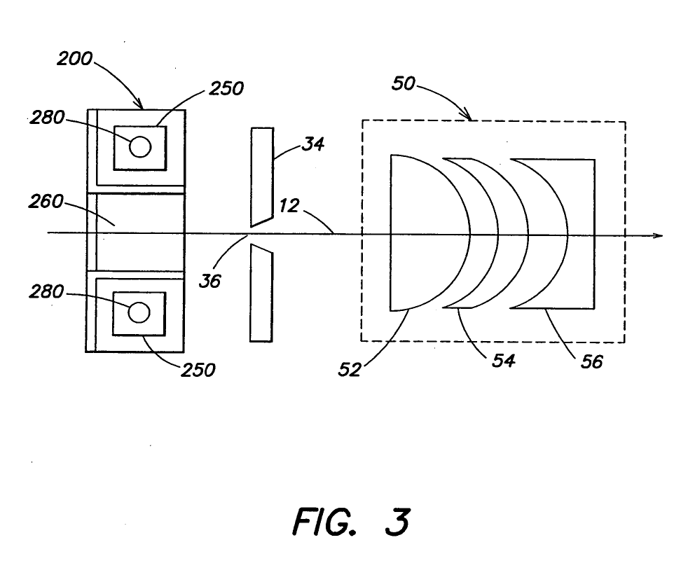

A section of the ion implanter beamline in accordance with a first embodiment of the invention is shown in FIG. 3. A magnetic steerer 200 is positioned upstream of resolving aperture 36 and is configured to perform magnetic steering of ion beam 12. Magnetic steerer 200 may correct, at least partially, unwanted deviations of ion beam 12 from the beam path. The beam path is the nominal path followed by ion beam 12 through the ion optical elements of the ion implanter from ion source 10 to wafer 72 when the ion implanter is operating within acceptable limits. Magnetic steerer 200 is characterized by a relatively small insertion length along the beam path and can perform vertical steering, horizontal steering, or both, depending on its configuration. For example, magnetic steerer 200 can steer ion beam 12 through resolving aperture 36, through electrodes 52, 54 and 56 of deceleration stage 50 and between the polepieces of angle corrector magnet 60 (FIG. 1). Steering corrections in the plane normal to the angle of bending in the magnet are typically done in combination with a partial correction by the extraction manipulator near the ion source. Corrections in the direction of beam dispersion are done in combination with small changes in the strength of the bending magnet consistent with the angular acceptance of the mass resolving slit. Magnetic steerer 200 is described in detail below.

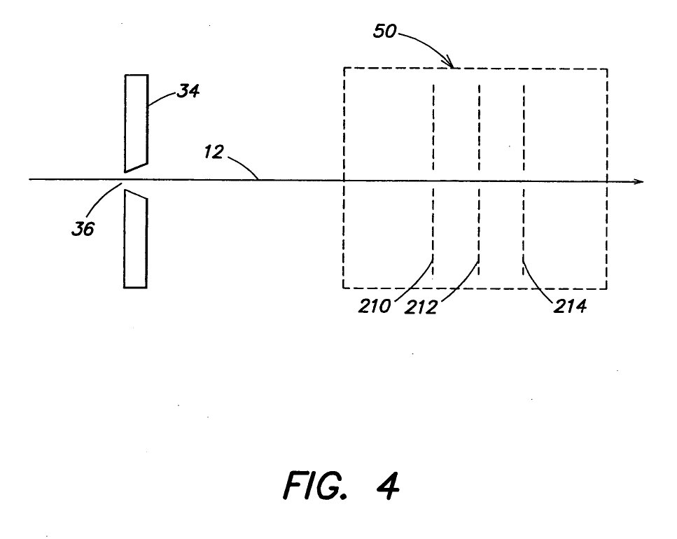

A section of the ion implanter beamline in accordance with a second embodiment of the invention is shown in FIG. 4. In the embodiment of FIG. 4, deceleration stage 50 is configured with at least one grid electrode. The deceleration stage 50 shown in FIG. 4 includes an upstream electrode 210, a suppression electrode 212, and a deceleration electrode 214, each of which is configured as a grid electrode. In general, the grid electrode is a conductor having a relatively small dimension along the beam path and having multiple openings for passing ion beam 12. Each grid electrode is electrically connected to a suitable bias voltage.

The grid electrode offers several advantages. Since the potential can be defined in an essentially zero length electrode, the total effective lens length and the region of deneutralization can be reduced to a minimum. The grid electrode causes the diverging portion of the gap lens fields to be eliminated and converts the lens to strong focus as a consequence, allowing the lens to work more effectively to overcome the divergence produced by the region of space charge decompensation. When focusing is not required (due to other elements providing adequate focusing), the focus of either gap of the lens system can be turned off by gridding the outside electrode of the gap. Further focus control is offered in the single grid electrode system by varying the aperture of the outside electrodes since the focal strength scales with the basic aperture dimensions. Single or dual grids can be shaped in three dimensions to compensate for some of the aberrations of injected beams since the potentials must follow the grid shapes for grid openings small compared to the gap separations regardless of the beam energy and current. The use of this type of lens maximizes the matching capability with a given pole geometry of the final parallelizing magnet.

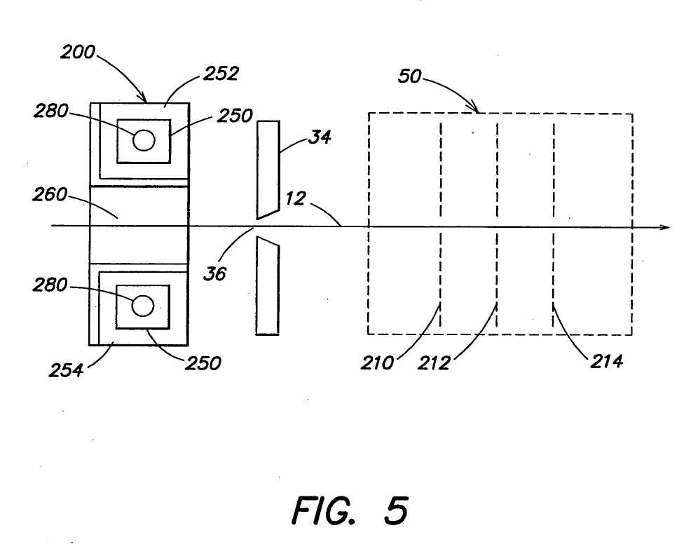

A section of the ion implanter beamline in accordance with a third embodiment of the invention is shown in FIG. 5. In the embodiment of FIG. 5, magnetic steerer 200 is located upstream of resolving aperture 36, and deceleration stage 50 includes grid electrodes 210, 212, and 214. As a result, the benefits of magnetic steerer 200 and grid electrodes 210, 212, and 214 in achieving low energy ion beam transport through the ion implanter are combined.

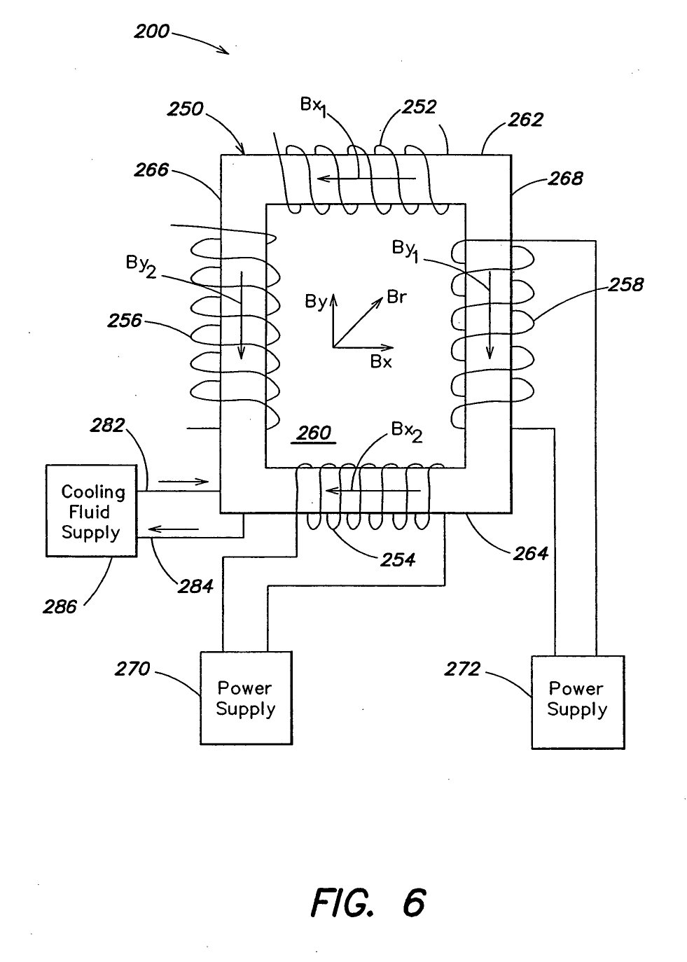

A schematic diagram of an embodiment of magnetic steerer 200 and associated system elements is shown in FIG. 6. Magnetic steerer 200 is viewed in the direction of ion beam transport in FIG. 6. Magnetic steerer 200 includes a magnetic frame 250 and one or more electrical coils wound around magnetic frame 250. The embodiment of FIG. 6 includes coils 252 and 254 for producing x-direction magnetic fields Bₓ, and coils 256 and 258 for producing y-direction magnetic fields By,

Magnetic frame 250 may be a closed loop band of steel or other magnetic material having a central opening 260 for passing the ion beam. In the embodiment of FIG. 6, magnetic frame 250 has a rectangular shape including a top segment 262, a bottom segment 264, a left-side segment 266 and a right-side segment 268. Coil 252 is wound around top segment 262; coil 254 is wound around bottom segment 264; coil 256 is wound around left-side segment 266; and coil 258 is wound around right-side segment 268.

The coils 252 and 254 may be connected to a power supply 270, and coils 256 and 258 may be connected to a power supply 272. The coils 252 and 254 are connected to produce an x-direction magnetic field Bₓ in opening 260, and coils 256 and 258 are connected to produce a y-direction magnetic field B_{y} in opening 260. In particular, coils 252 and 254 are wound and energized by power supply 270 to produce opposing magnetic fields in magnetic frame 250. The opposing magnetic fields have a return path though opening 260. Similarly, coils 256 and 258 are wound and energized by power supply 272 to produce opposing magnetic fields in magnetic frame 250, and the opposing magnetic fields have a return path through opening 260. A resulting magnetic field Bᵣ is the vector sum of magnetic field Bₓ and magnetic field B_{y}. As known in the art, x-direction magnetic field Bₓ produces y-direction steering of the ion beam, and y-direction magnetic field B_{y} produces x-direction steering of the ion beam.

The magnetic steerer shown in FIG. 6 and described above can produce x-direction magnetic fields Bₓ and y-direction magnetic fields B_{y}. In some applications, only x-direction steering is required, and coils 252 and 254 may be omitted from the magnetic steerer. In other applications, only y-direction steering is required, and coils 256 and 258 may be omitted. In cases where a unidirectional magnetic field is sufficient, magnetic frame 250 may have permanent magnetic poles to improve the homogeneity and intensity of the magnetic field produced by the coils.

In one example, magnetic frame 250 had dimensions of 7.5 inches (in.)×7.5 in.×2 in. outside dimension by 0.75 in. thickness and was fabricated of type 1018 steel. Coils 252, 254, 256 and 258 each had 300 turns of No. 16 AWG wire, and power supplies 270 and 272 had output currents of 0 to 15 A. The magnetic steerer 200 had a dimension along the beam path of about 3 inches and produced deflections of about 0.64° of a 12 keV B⁺ ion beam with 1.2 A of coil current. It will be understood that a variety of different magnetic frame sizes and materials and coil configurations may be utilized within the scope of the invention. In one example, segments 262, 264, 266, and 268 of magnetic frame 250 were fabricated separately, had the respective coils installed thereon and then were bolted together to form magnetic steerer 200.

Depending on operating conditions, magnetic steerer 200 may require active cooling. In the embodiment shown in FIGS. 3, 5 and 6, magnetic frame 250 is provided with a fluid passage 280 (FIGS. 3 and 5) connected by fluid conduits 282 and 284 (FIG. 6) to a cooling fluid supply 286. During operation a cooling fluid, such as water, may be circulated through fluid passage 280 to limit the temperature rise of magnetic steerer 200. Cooling can also be incorporated by flowing coolant through hollow magnet wires or by wrapping cooling tubing in proximity to the coil windings.

It will be understood that magnetic steerer 200 is configured for at least partially correcting unwanted deviations of ion beam 12 from the beam path. Magnetic steerer 200 is not typically utilized for scanning ion beam 12 or for producing large deflections of ion beam 12. The unwanted deviation of ion beam 12 may result, for example, from magnetic fields in ion source 10 or from aberrations in analyzing magnet 32. Magnetic steerer 200 may be utilized to center ion beam 12 with respect to resolving aperture 36, the gap in deceleration stage 50 and/or the entrance aperture of angle corrector magnet 60. Magnetic steerer 200 may be configured to correct unwanted deviations of the ion beam perpendicular to the analysis plane of analyzing magnet 32, parallel to the analysis plane, or both.

The ion implanter is typically required to operate at different times with different ion species, different ion energies and different beam currents. The unwanted deviations of ion beam 12 are likely to be different for different ion beam parameters. Thus, when the ion beam parameters are changed, one or both of power supplies 270 and 272 may be adjusted to produce the desired correction of ion beam direction. During operation with a selected set of ion beam parameters, the outputs of power supplies 270 and 272 may remain fixed.

Magnetic steerer 200 has been shown and described as located upstream of resolving aperture 36. In other embodiments, a magnetic steerer can be positioned at any point along the beam path to at least partially correct unwanted deviations of the ion beam from the beam path. The magnetic steerer may be positioned upstream of an ion optical element having an entrance aperture. The magnetic fields of the steerer may be adjusted to position the ion beam relative to the entrance aperture. For example, the magnetic steerer may center the ion beam relative to the gap between polepieces of a magnet, such as angle corrector magnet 60 (FIG. 1).

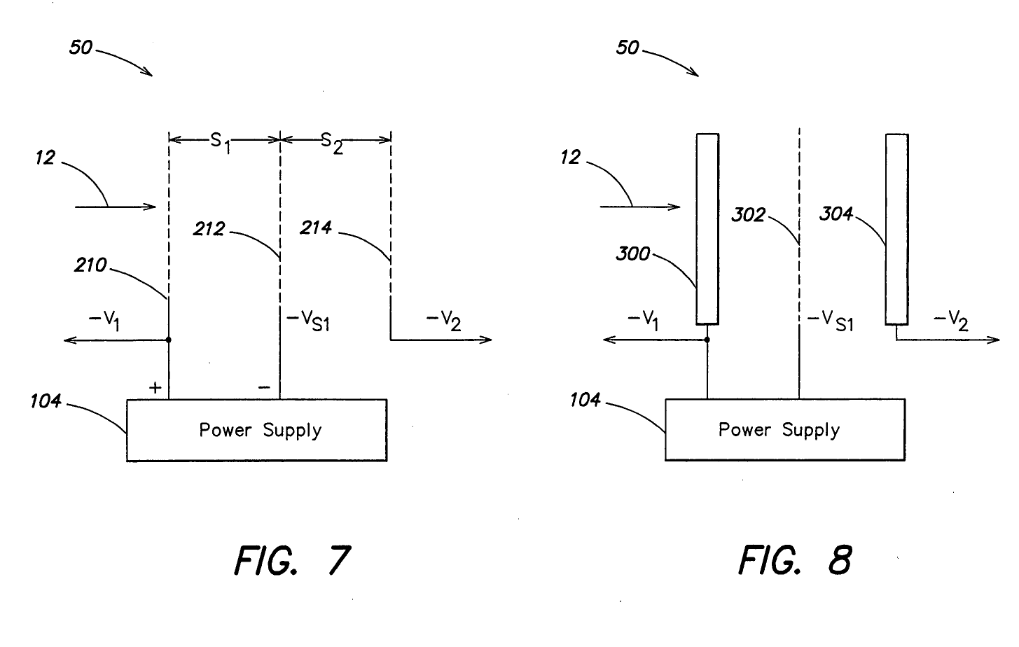

A schematic diagram of a first embodiment of deceleration stage 50 is shown in FIG. 7. Deceleration stage 50 includes grid electrode 210 (the upstream electrode), grid electrode 212 (the suppression electrode), and grid electrode 214 (the deceleration electrode). Grid electrode 210 is connected to power supply 102 (FIG. 1) which produces voltage V₁. Power supply 104 is referenced to power supply 102 and may bias grid electrode 212 more negatively than voltage V₁ by a voltage V_{S1} equal to or greater than about −1 kV. Grid electrode 214 is connected to power supply 122 (FIG. 1) which produces negative voltage V₂. In a typical configuration, a spacing S₁ between grid electrodes 210 and 212 may be in a range of about 0.2 in. to 2 in., and a spacing S₂ between grid electrodes 212 and 214 may be in a range of about 0.5 in. to 3 in.

A schematic diagram of a second embodiment of deceleration stage 50 is shown in FIG. 8. In the embodiment of FIG. 8, deceleration stage 50 includes a conventional upstream electrode 300, a grid suppression electrode 302 and a conventional deceleration electrode 304. Upstream electrode 300 is connected to voltage V₁, grid electrode is connected to voltage V_{S1}, and deceleration electrode 304 is connected to voltage V₂. In the embodiment of FIG. 8, grid electrode 302 has the advantage of providing a containment barrier for electrons to minimize the region of space charge stripping and also strong focusing in both the acceleration and deceleration gaps of the system. In general, one or more of the electrodes in deceleration stage 50 may be configured as a grid electrode.

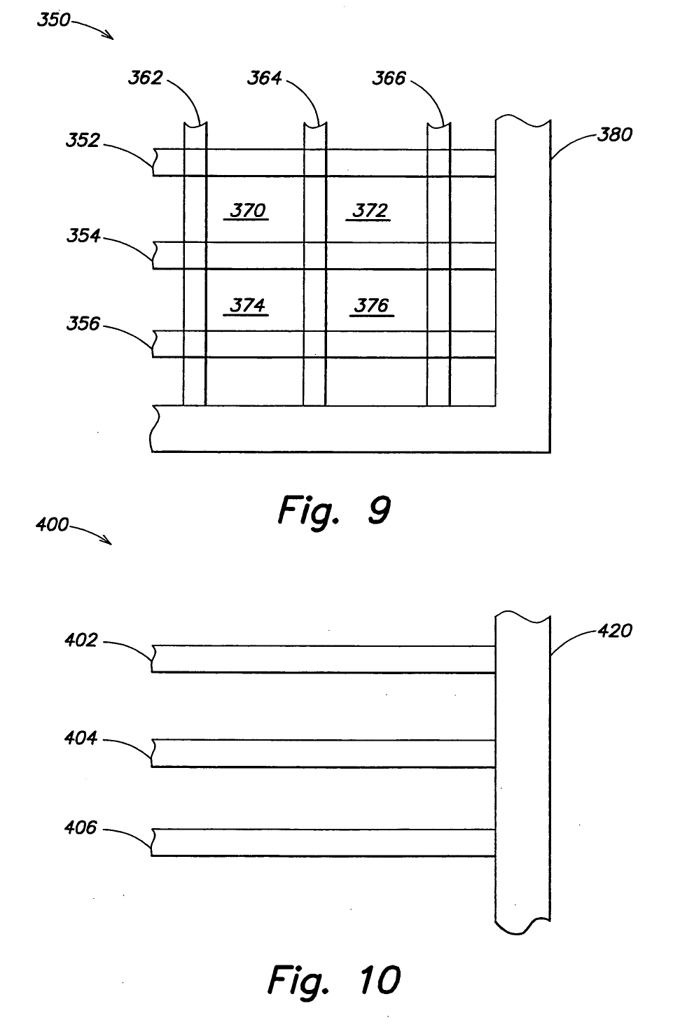

A first embodiment of a grid electrode as viewed along the direction of beam transport is shown in FIG. 9. A grid electrode 350 may include spaced-apart x-direction conductors 352, 354, 356, etc. and spaced-apart y-direction conductors 362, 364, 366, etc., which define an array of openings 370, 372, 374, 376, etc. for passage of ion beam 12. The x-direction conductors 352, 354, 356, etc. may be parallel to each other. The y-direction conductors 362, 364, 366, etc. may be parallel to each other and may be orthogonal to the x-direction conductors. It will be understood that the grid electrode is not limited to this configuration. The conductors of grid electrode 350 may be supported by a conductive frame 380, so that the entire electrode is at one electrical potential. Parameters of the grid electrode 350 include the diameters of the conductors and the spacings between conductors. These parameters determine the dimensions of openings 370, 372, 374, and 376 and the extent to which ion beam 12 is blocked by the conductors of the grid electrode.

In general, the selection of conductor size and conductor spacing is a tradeoff between the desire to fill as much as possible of the area traversed by ion beam 12 with conductors at a single potential and the desire to avoid blocking the ion beam. Beam blocking reduces the total current delivered to the target. In addition, the conductors cause shadowing which can potentially produce spatial non-uniformities in the ion beam delivered to the target. Furthermore, the conductors of the grid electrode may be sputtered by the energetic ion beam and should have sufficient size to limit the need for frequent replacement. Sputtering of the grid electrode conductors may produce some beam contamination. However, the contaminants are separated from the ion beam upon passage through angle corrector magnet 60 (FIG. 1).

For many applications, grid electrode conductors 352, 354, 356, 362, 364, 366, etc. may have thicknesses in a range of about 0.001 in. to 0.02 in. and spacings between conductors in a range of about 0.02 in. to 0.5 in. Suitable materials include tungsten, carbon and tantalum.

A second embodiment of a grid electrode as viewed along the direction of beam transport is shown in FIG. 10. The grid electrode 400 includes spaced-apart conductors 402, 404, 406, etc. supported by a conductive frame 420. Conductors 402, 404, 406, etc. may be x-direction conductors or y-direction conductors and may be parallel to each other. The embodiment of FIG. 10 may have the advantage of producing less non-uniformity at the target as compared with the grid electrode 350 shown in FIG. 9 and described above. In one application, electrodes 402, 404, 406, etc. are parallel to the long dimension of a ribbon ion beam cross section. The considerations described above with respect to selection of conductor diameter and spacing apply to the embodiment of FIG. 10.

In some embodiments, the grid electrode is planar and is mounted perpendicular to the direction of ion beam transport. In other embodiments, the grid electrode is shaped or contoured to produce a desired result. For example, the grid electrode may have a cylindrical or spherical shape or may have an arbitrary nonplanar shape. Nonplanar shapes may be used to correct for aberrations of asymmetries in the ion beam by applying different focusing strength for different regions of the ion beam. The grid electrode may be contoured to be perpendicular to diverging or converging ion trajectories.

In some embodiments, the grid electrode may include multiple conductors as described above. For example, the grid electrode may have a woven configuration and may be in the form of a screen. In other embodiments, the grid electrode may include a single conductor having multiple openings.

The grid electrodes have been described in connection with use in deceleration stage 50. In other embodiments, one or more grid electrodes can be used at other locations along the beam path. Care should be taken to control target contamination, beam current reduction and reduction in dose uniformity within acceptable limits.

The grid electrodes have the advantage of a strong focus with reduced beam blowup resulting from space charge neutralization. The spacing between electrodes along the beam path can be relatively small. Thus, the region of electric field interaction with the ion beam is reduced, and space charge neutralization is reduced.

Having thus described several aspects of at least one embodiment of this invention, it is to be appreciated various alterations, modifications, and improvements will readily occur to those skilled in the art. Such alterations, modifications, and improvements are intended to be part of this disclosure, and are intended to be within the spirit and scope of the invention. Accordingly, the foregoing description and drawings are by way of example only.

What is claimed is:

1. An ion implanter comprising:
an ion source for generating an ion beam;
a target site for supporting a target for ion implantation;
a beamline defining a beam path between the ion source and the target site; and
a magnetic steerer disposed between the ion source and the target site for at least partially correcting an unwanted deviation of the ion beam from the beam path.

2. An ion implanter as defined in claim 1, wherein the magnetic steerer comprises a closed-loop magnetic frame having an opening for passing the ion beam and one or more electrical coils on the frame for producing a magnetic field in the opening.

3. An ion implanter as defined in claim 2, wherein the magnetic frame has a generally rectangular shape.

4. An ion implanter as defined in claim 2, wherein the magnetic frame includes top, bottom, left-side and right-side segments.

5. An ion implanter as defined in claim 4, wherein the magnetic steerer includes electrical coils on the top and bottom segments of the magnetic frame.

6. An ion implanter as defined in claim 4, wherein the magnetic steerer includes electrical coils on the left-side and right-side segments of the magnetic frame.

7. An ion implanter as defined in claim 4, wherein the magnetic steerer includes electrical coils on the top, bottom, left-side and right-side segments of the magnetic frame.

8. An ion implanter as defined in claim 1, wherein the magnetic steerer comprises a rectangular frame of magnetic material having an opening for passing the ion beam and electrical coils on at least two opposite sides of the rectangular frame.

9. An ion implanter as defined in claim 1, wherein the beamline comprises a mass analyzing magnet positioned upstream of the magnetic steerer for separating different ion species in an analysis plane and a resolving mask having a resolving aperture positioned downstream of the magnetic steerer for selecting one of the species, wherein the magnetic steerer directs the ion beam through the resolving aperture.

10. An ion implanter as defined in claim 9, wherein the magnetic steerer is configured to correct unwanted deviation of the ion beam perpendicular to the analysis plane.

11. An ion implanter as defined in claim 9, wherein the beamline further comprises a deceleration stage positioned downstream of the resolving mask.

12. An ion implanter as defined in claim 11, wherein the beamline further comprises an angle corrector magnet positioned downstream of the deceleration stage.

13. An ion implanter as defined in claim 9, wherein the unwanted deviation of the ion beam is produced by magnetic fields in the ion source.

14. An ion implanter as defined in claim 9, wherein the unwanted deviation of the ion beam is produced by aberrations in the mass analyzing magnet.

15. An ion implanter as defined in claim 1, wherein the beamline includes an ion optical element having an entrance aperture and wherein the magnetic steerer is configured to position the ion beam relative to the entrance aperture.

16. An ion implanter as defined in claim 1, wherein the ion source includes an element which produces unwanted deviation of the ion beam from the beam path.

17. An ion implanter comprising:
an ion source for generating an ion beam;
an analyzer for a separating unwanted components from the ion beam, wherein the ion beam is transported through said analyzer at a first transport energy;
a deceleration stage positioned downstream of said analyzer for decelerating the ion beam from the first transport energy to a second transport energy, said deceleration stage comprising an upstream electrode and a deceleration electrode, wherein at least one of said electrodes comprises a grid electrode positioned in the beam path; and
a target site for supporting a target for ion implantation.

18. An ion implanter as defined in claim 17, wherein the grid electrode comprises plural spaced conductors defining openings for passing the ion beam.

19. An ion implanter as defined in claim 17, wherein the grid electrode comprises a first set of spaced-apart parallel conductors and a second set of spaced-apart parallel conductors, wherein the conductors in the first set are orthogonal to the conductors in the second set.

20. An ion implanter as defined in claim 17, wherein the grid electrode is substantially planar and is oriented perpendicular to the ion beam.

21. An ion implanter as defined in claim 17, wherein the grid electrode is nonplanar and is configured to adjust for aberrations in the ion beam entering the deceleration stage.

22. An ion implanter as defined in claim 17, wherein the deceleration electrode comprises a grid electrode positioned in the beam path.

23. An ion implanter as defined in claim 17, wherein the deceleration stage further comprises a suppression electrode between the upstream and deceleration electrodes and wherein the suppression electrode comprises a grid electrode positioned in the beam path.

24. An ion implanter as defined in claim 23, wherein each of the electrodes of the deceleration stage comprises a grid electrode.

25. An ion implanter as defined in claim 17, wherein the grid electrode comprises a conductor having multiple openings for passing the ion beam.

26. An ion implanter as defined in claim 17, further comprising a beam filter positioned downstream of the deceleration stage for separating neutral particles from the ion beam.

27. An ion implanter as defined in claim 26, wherein the beam filter comprises an angle corrector magnet.

28. An ion implanter as defined in claim 17, wherein the analyzer comprises an analyzing magnet and a resolving mask having a resolving aperture, the ion implanter further comprising a magnetic steerer positioned between the analyzing magnet and the resolving aperture for at least partially correcting an unwanted deviation of the ion beam from the beam path.

29. An ion implanter as defined in claim 17, wherein the grid electrode comprises a screen.

30. An ion implanter as defined in claim 17, wherein the grid electrode comprises a plurality of spaced-apart parallel conductors disposed in the beam path.

31. An ion implanter comprising:
an ion source for generating an ion beam;
a target site for supporting a target for ion implantation; and
a grid electrode disposed between the ion source and the target site for altering at least one parameter of the ion beam, said grid electrode having multiple openings for passing the ion beam.

32. A method for implanting ions in a target, comprising:
generating an ion beam;
supporting a target at a target site for ion implantation;
transporting the ion beam along a beam path between the ion source and the target site; and
at least partially correcting an unwanted deviation of the ion beam from the beam path using a magnetic steerer disposed between the ion source and the target site.

33. A method for implanting ions in a target, comprising:
generating an ion beam;
separating unwanted components from the ion beam in an analyzer;
transporting the ion beam through the analyzer at a first transport energy;
decelerating the ion beam from the first transport energy to a second transport energy in a deceleration stage comprising two or more electrodes, wherein at least one of the electrodes comprises a grid electrode disposed in the beam path; and
delivering the decelerated ion beam to a target site.
